(19) United States
(12) Patent Application Publication
(10) Pub. No.: US 2014/0062550 A1
(43) Pub. Date: Mar. 6, 2014

(54) PHASE LOCKED LOOP

(71) Applicant: REALTEK SEMICONDUCTOR CORP., Hsinchu (TW)

(72) Inventors: Chao-Cheng Lee, Hsin-Chu City (TW); Hai-Bing Zhao, Jiangsu (CN)

(73) Assignee: REALTEK SEMICONDUCTOR CORP., Hsinchu (TW)

(21) Appl. No.: 14/016,319

(22) Filed: Sep. 3, 2013

(30) Foreign Application Priority Data
Sep. 5, 2012 (CN) 201210325246.7

(51) Int. Cl. H03L 7/093

(52) U.S. Cl. CPC H03L 7/093
USPC 327/157

(57) ABSTRACT

A phase locked loop comprises a loop filter and a charge pump circuit. The loop filter comprises a parallel capacitor, a serial resistor and a serial capacitor. A first terminal of the serial resistor is electrically connected to a first terminal of the parallel capacitor. A first terminal of the serial capacitor is electrically connected to the second terminal of the serial resistor, and a second terminal of the serial capacitor is electrically connected to a second terminal of the parallel capacitor. The charge pump circuit comprises a first charge pump and a second charge pump. The first charge pump is electrically connected to the first terminal of the serial resistor, and the second charge pump is electrically connected to the second terminal of the serial resistor. The phase lock loop can reduce output jitter and therefore increases the performance of the phase lock loop.

This application claims the benefit of People's Republic of China application Serial No. 201210325246.7, filed Sep. 5, 2012, the subject matter of which is incorporated herein by reference.

### BACKGROUND OF THE INVENTION

1. Field of the Invention

The invention relates in general to a loop, and more particularly to a phase lock loop.

2. Description of the Related Art

Referring to FIG. 1, a schematic diagram of a conventional phase lock loop (PLL) is shown. The conventional phase lock loop 1 comprises a charge pump 11, a loop filter 12, a voltage controlled oscillator 13 and a phase frequency detector 15. The voltage controlled oscillator 13 generates an oscillation signal φₒᵤₜ according to the output of the loop filter 12. The phase frequency detector 15 controls the charge pump 11 according to the oscillation signal φₒᵤₜ and the reference clock signal CLK.

The loop filter 12 comprises a parallel capacitor Cₚ, a serial resistor Rₛ and a serial capacitor Cₛ. The serial resistor Rₛ has a first terminal electrically connected to a first terminal of the parallel capacitor Cₚ. The serial capacitor Cₛ has a first terminal electrically connected to a second terminal of the serial resistor Rₛ. The serial capacitor Cₛ has a second terminal electrically connected to a second terminal of the parallel capacitor Cₚ.

The charge pump 11 is electrically connected to the first terminal of the serial resistor Rₛ. In more details, the charge pump 11 comprises a current source 11a, a switch SW1, a current source 11b and a switch SW2. The current source 11a and the current source 11b respectively provide a current I_{cp}. The switch SW1 is controlled by switch signal UP to electrically connect the current source 11a to the first terminal of the serial resistor Rₛ. The switch SW2 is controlled by switch signal DN to electrically connect the current source 11b to the first terminal of the serial resistor Rₛ. However, the serial resistor Rₛ of the conventional phase lock loop 1 may generate noises and cause output jitter so as to affect the performance of the conventional phase lock loop 1.

### SUMMARY OF THE INVENTION

The invention is directed to a phase lock loop (PLL).

According to one embodiment of the present invention, phase locked loop (PLL) comprising a loop filter and a charge pump circuit is disclosed. The loop filter comprises a parallel capacitor, a serial resistor and a serial capacitor. A first terminal of the serial resistor is electrically connected to a first terminal of the parallel capacitor. A first terminal of the serial capacitor is electrically connected to a second terminal of the serial resistor, and a second terminal of the serial capacitor is electrically connected to a second terminal of the parallel capacitor. The charge pump circuit comprises a first charge pump and a second charge pump. The first charge pump is electrically connected to the first terminal of the serial resistor, and the second charge pump is electrically connected to the second terminal of the serial resistor. The phase lock loop can reduce output jitter and therefore increases the performance of the phase lock loop.

The phase lock loop of the invention can reduce output jitter and therefore increases the performance of the phase lock loop.

The above and other aspects of the invention will become better understood with regard to the following detailed description of the preferred but non-limiting embodiment (s). The following description is made with reference to the accompanying drawings.

### BRIEF DESCRIPTION OF THE DRAWINGS

FIG. 1 shows a schematic diagram of a conventional phase lock loop (PLL).

FIG. 2 shows a schematic diagram of a phase lock loop according to a first embodiment.

FIG. 3 shows a partial equivalent circuit of FIG. 1.

FIG. 4 shows a partial equivalent circuit of FIG. 2.

FIG. 5 shows a schematic diagram of a phase lock loop according to a second embodiment.

### DETAILED DESCRIPTION OF THE INVENTION

### First Embodiment

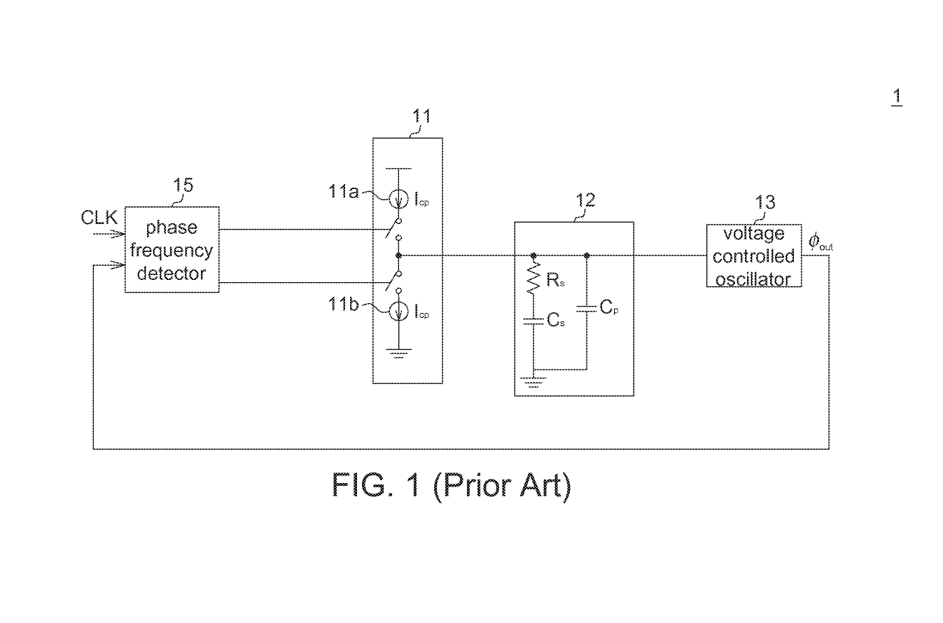

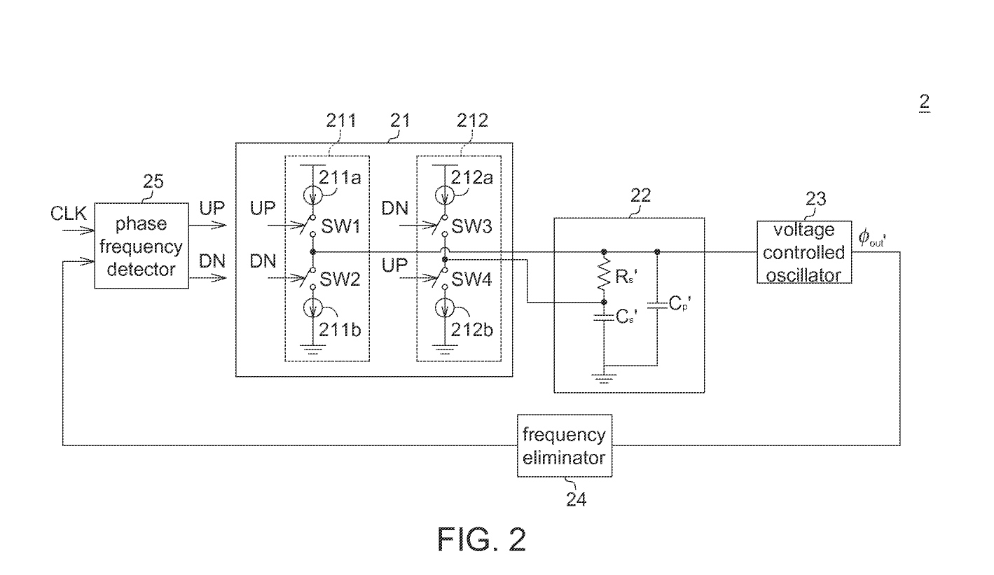

Referring to FIG. 1 and FIG. 2, FIG. 2 shows a schematic diagram of a phase lock loop according to a first embodiment of present invention. The phase lock loop 2 comprises a charge pump circuit 21, a loop filter 22, a voltage controlled oscillator 23, a frequency eliminator 24 and a phase frequency detector 25. The voltage controlled oscillator 23 generates an oscillation signal φout′ according to the output of the loop filter 22. The phase frequency detector 25 provides a switch signal UP and a switch signal DN according to the oscillation signal φout′ and the reference clock signal CLK.

The loop filter 22 comprises a parallel capacitor Cp′, a serial resistor Rs′ and a serial capacitor Cs′. The serial resistor Rs′ has a first terminal electrically connected to a first terminal of the parallel capacitor Cp′. The serial capacitor Cs′ has a first terminal electrically connected to a second terminal of the serial resistor Rs′. The serial capacitor Cs′ has a second terminal electrically connected to a second terminal of the parallel capacitor Cp′. As mentioned, the serial resistor Rs contributes jitter source of the phase lock loop 1. In order to reduce output jitter, the resistance of the serial resistor Rs′ of the phase lock loop 2 is equal to Rs/N, the capacitance of the parallel capacitor Cp′ is equal to N times of the parallel capacitor Cp, and the capacitance of the serial capacitor Cs′ is equal to the serial capacitor Cs minus (N−1) times of the parallel capacitor Cp, wherein N is a real number greater than 1.

The charge pump circuit 21 comprises a charge pump 211 and a charge pump 212. The charge pump 211 is electrically connected to the first terminal of the serial resistor Rs′. The charge pump 212 is electrically connected to the second terminal of the serial resistor Rs′. In more details, the charge pump 211 comprises a current source 211a, a switch SW1, a current source 211b and a switch SW2. The current source 211a and the current source 211b respectively provide N times of the current Icp. The switch SW1 is controlled by switch signal UP to electrically connect the current source 211a to the first terminal of the serial resistor Rs′. The switch SW2 is controlled by switch signal DN to electrically connect the current source 211b to the second terminal of the serial resistor Rs′. The charge pump 212 comprises a current source 212a, a switch SW3, a current source 212b and a switch SW4. The current source 212a and the current source 212b respectively provide (N−1) times of the current Icp. It is noticed that the current provided by the current source 211a and 211b is different from the current provided by the current source 212a and 212b. In other words, the current charged into the first terminal of the serial resistor Rs′ is different from the current discharged from the second terminal of the serial resistor Rs′.

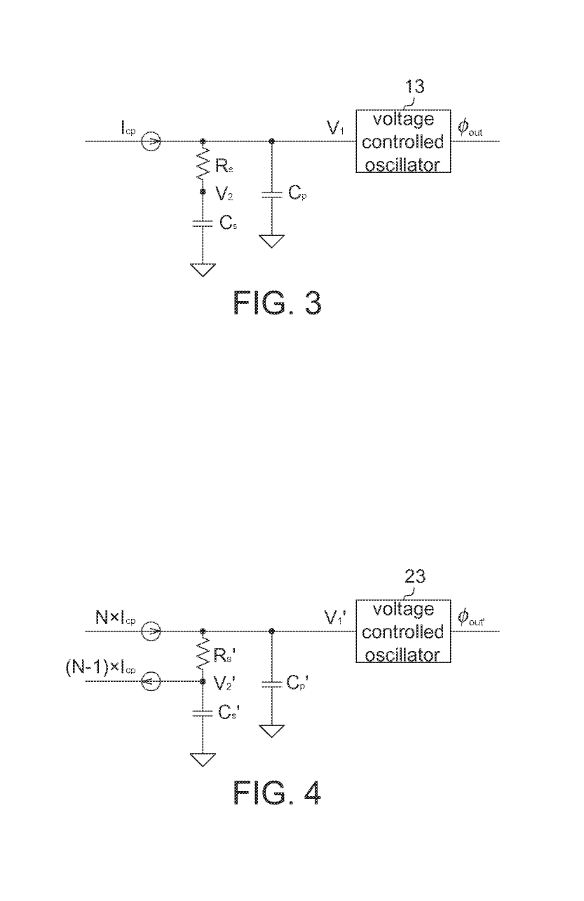

Referring to FIG. 3 and FIG. 4, FIG. 3 shows a partial equivalent circuit of FIG. 1. FIG. 4 shows a partial equivalent circuit of FIG. 2. According to FIG. 3, formula 1 can be obtained as below.

$$\begin{matrix}\{ \begin{matrix}{V}_{1} {C}_{p} s + \frac{{V}_{1} - {V}_{2}}{{R}_{s}} = {I}_{CP} \\ {V}_{2} {C}_{s} s = \frac{{V}_{1} - {V}_{2}}{{R}_{s}}\end{matrix} \\ \begin{matrix}⇒ {V}_{1} = - \frac{1 + {R}_{s} {C}_{s} s}{{R}_{s} {C}_{s} {C}_{p} {s}^{2} + {C}_{p} s + {C}_{s} s} \times {I}_{cp} \\ = \frac{\frac{1}{{C}_{p}} ( s + \frac{1}{{R}_{s} {C}_{s}} )}{s ( s + \frac{1}{{R}_{s} {C}_{p}} + \frac{1}{{R}_{s} {C}_{s}} )} \times {I}_{cp}\end{matrix}\end{matrix} \qquad ( Formula 1 )$$

Based on FIG. 4, formula 2 can be obtained as below.

$$\begin{matrix}\{ \begin{matrix}{V}_{1}^{′} {C}_{p}^{′} s + \frac{{V}_{1}^{′} - {V}_{2}^{′}}{{R}_{s}^{′}} = N \times {I}_{cp} \\ {V}_{2}^{′} {C}_{s}^{′} s + ( N - 1 ) {I}_{cp} = \frac{{V}_{1}^{′} - {V}_{2}^{′}}{{R}_{2}^{′}}\end{matrix} & ( Formula 2 ) \\ \begin{matrix}⇒ {V}_{1}^{′} = - \frac{1 + {NR}_{2}^{′} {C}_{s}^{′} s}{{R}_{s}^{′} {C}_{s}^{′} {C}_{p}^{′} {s}^{2} + {C}_{p}^{′} s + {C}_{s}^{′} s} \times {I}_{cp} \\ = \frac{\frac{N}{{C}_{p}} ( s + \frac{1}{{NR}_{s}^{′} {C}_{s}^{′}} )}{s ( s + \frac{1}{{R}_{s}^{′} {C}_{p}^{′}} + \frac{1}{{R}_{s}^{′} {C}_{s}^{′}} )} \times {I}_{cp}\end{matrix} & \end{matrix}$$

Wherein, voltage V1 is equal to voltage V1′. Based on the comparison between formula 1 and formula 2, the following formula can be obtained.

$$\{ \begin{matrix}{C}_{p}^{′} = {NC}_{p} & \\ \frac{1}{{R}_{s} {C}_{s}} = \frac{1}{{NR}_{s}^{′} {C}_{s}^{′}} & ⇒ \\ \frac{1}{{R}_{s} {C}_{p}} + \frac{1}{{R}_{s} {C}_{s}} = \frac{1}{{R}_{s}^{′} {C}_{p}^{′}} + \frac{1}{{R}_{s}^{′} {C}_{s}^{′}} & \end{matrix} \\ {C}_{p}^{′} = {NC}_{p} \\ {C}_{s}^{′} = {C}_{s} - ( N - 1 ) {C}_{p} \\ {R}_{s}^{′} = \frac{{R}_{s}}{N} \times \frac{1}{1 - ( N - 1 ) \frac{{C}_{p}}{{C}_{s}}} \\ ∵ {C}_{p} << {C}_{s} \\ ∴ {R}_{s}^{′} \approx \frac{{R}_{s}}{N} \\ {C}_{p}^{′} = {NC}_{p} \\ {C}_{s}^{′} = {C}_{s} - ( N - 1 ) {C}_{p}$$

Given that the phase lock loop 2 and the conventional phase lock loop 1 have the same transfer function, the resistance of the serial resistor Rs′ is equal to Rs/N, the capacitance of the parallel capacitor Cp′ is equal to N×Cp, and the capacitance of the serial capacitor Cs′ is equal to Cs−(N−1)*Cp, wherein N is a positive real number greater than 1.

### Second Embodiment

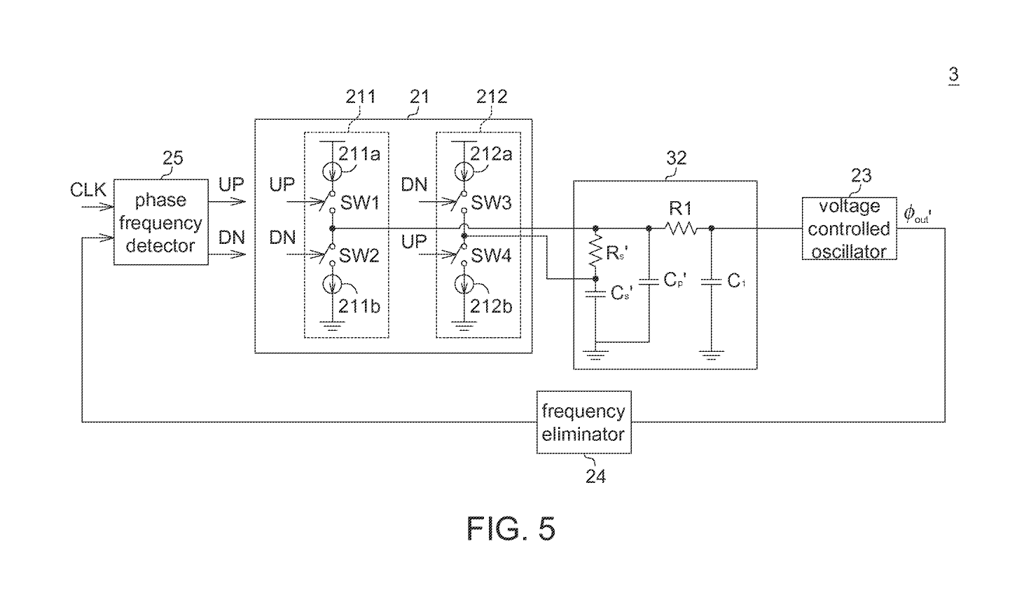

Referring to FIG. 5, a schematic diagram of a phase lock loop according to a second embodiment is shown. The second embodiment is different from the first embodiment in that the phase lock loop 3 uses a third-order loop filter 32. In addition to the parallel capacitor Cₚ′, the serial resistor Rₛ′ and the serial capacitor Cₛ′, the loop filter 32 further comprises a resistor R1 and a capacitor C₁. A first terminal of the resistor R1 is electrically connected to the first terminal of the serial resistor Rₛ′. A first terminal of the capacitor C₁ is electrically connected to a second terminal of the resistor R1. A second terminal of the capacitor C1 is electrically connected to the second terminal of the serial capacitor Cs′. In other embodiments, the phase lock loop can use a loop filter of other orders.

While the invention has been described by way of example and in terms of the preferred embodiment (s), it is to be understood that the invention is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A phase lock loop (PLL), comprising:
a loop filter and a charge pump circuit; wherein
the loop filter comprises:
a parallel capacitor having a first terminal and a second terminal;
a serial resistor having a first terminal and a second terminal, wherein the first terminal of the serial resistor is electrically connected to the first terminal of the parallel capacitor; and
a serial capacitor having a first terminal and a second terminal, wherein the first terminal of the serial capacitor is electrically connected to the second terminal of the serial resistor, and the second terminal of the serial capacitor is electrically connected to the second terminal of the parallel capacitor; and the charge pump circuit comprises:
a first charge pump electrically connected to the first terminal of the serial resistor; and
a second charge pump electrically connected to the second terminal of the serial resistor.

2. The phase lock loop according to claim 1, wherein the first charge pump comprises:
a first current source;
a first switch controlled by a first switch signal to electrically connect the first current source to the first terminal of the serial resistor;
a second current source; and
a second switch controlled by a second switch signal to electrically connect the second current source to the first terminal of the serial resistor.

3. The phase lock loop according to claim 2, wherein the current provided by the first current source is the same as the current provided by the second current source.

4. The phase lock loop according to claim 2, wherein the second charge pump comprises:
a third current source;
a third switch controlled by the second switch signal to electrically connect the third current source to the second terminal of the serial resistor;
a fourth current source; and
a fourth switch controlled by the first switch signal to electrically connect to the fourth current source the second terminal of the serial resistor.

5. The phase lock loop according to claim 4, wherein the current provided by the third current source is the same as the current provided by the fourth current source.

6. The phase lock loop according to claim 4, wherein the current provided by the first current source is different from the current provided by the third current source.

7. The phase lock loop according to claim 1, wherein the current charged into the first terminal of the serial resistor is different from the current discharged from the second terminal of the serial resistor.

8. The phase lock loop according to claim 1, wherein the loop filter further comprises:
a resistor having a first terminal and a second terminal, wherein the first terminal of the resistor is electrically connected to the first terminal of the serial resistor;
a capacitor having a first terminal and a second terminal, wherein the first terminal of the capacitor is electrically connected to the second terminal of the resistor, and the second terminal of the capacitor is electrically connected to the second terminal of the serial capacitor.

9. The phase lock loop according to claim 2, further comprising:
a voltage controlled oscillator used for generating an oscillation signal according to an output of the loop filter; and
a phase frequency detector used for providing the first switch signal and the second switch signal according to the oscillation signal and a clock signal.
